(19) United States
(12) Patent Application Publication
(10) Pub. No.: US 2008/0186057 A1
(43) Pub. Date: Aug. 7, 2008

(54) LOW FREQUENCY DETECTOR INCLUDING COMMON INPUT VOLTAGE SENSOR

(75) Inventors: Otani Daijiro, Tokyo (JP); Hisao Ogiwara, Koga-shi (JP)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/020,975

(22) Filed: Jan. 28, 2008

Related U.S. Application Data
(60) Provisional application No. 60/887,735, filed on Feb. 1, 2007.

(51) Int. Cl. H03K 19/0175

(52) U.S. Cl. 326/73

(57) ABSTRACT

A low frequency detector circuit includes a differential input that is received by an offset comparator circuit. The offset comparator circuit provides respective output signals COMPX and COMPY which can be compared to a generated threshold voltage Vcomp by an E2C (ECL to CMOS) comparators. The outputs of the E2C comparators are used by respective timers to generate fault signals. In addition to detecting low frequency conditions, common voltage conditions can be detected as well and can be distinguished at very high frequency conditions.

### CROSS-REFERENCE TO RELATED APPLICATIONS

This application claims the benefit of the filing date of copending provisional application U.S. Ser. No. 60/887,735, filed Feb. 1, 2007, entitled “Low Input Frequency Detector Including Common Input Voltage Sensor with AC Reset Helper”, which is incorporated by reference herein.

### STATEMENT OF FEDERALLY SPONSORED RESEARCH OR DEVELOPMENT

Not Applicable

### BACKGROUND OF THE INVENTION

1. Technical Field

This invention relates in general to integrated circuits and, more particularly, to a low frequency detector.

2. Description of the Related Art

A low frequency detector is used in a pre-amplifier for detecting the length of time between toggles (“flips”) of a differential write data input. If the length of time is too long, indicating a frequency which is too low, a fault state is reported.

For applications such in a pre-amplifier of a hard disk drive, the low frequency detector operates at a PECL (Positive Emitter-Coupled Logic) logic level, while the fault must be reported in a CMOS logic level. Therefore, the signal must be converted from PECL to CMOS at the detector.

A normal ECL to CMOS logic level comparator (E2C) does not function at a sufficiently high frequency due to the rail-to-rail swing of the CMOS output Therefore, as the input frequency increases, the input signal looks to the E2C circuit as if the differential input has the same common voltage in X and Y. This can cause mistaken detections of low frequency (miss-detections). Accordingly, in order to avoid miss-detections at a high frequency input, the circuit must turn the output to “safe” if both the X and Y inputs appear to have the same common voltage in a DC state.

In some cases, possibly due to an error, the differential inputs may actually be at the same common voltage (i.e., 0 volt differential), and it is necessary to detect this state. However, in current embodiments, a high frequency condition cannot be distinguished from a zero differential condition.

Therefore, a need has arisen for a circuit to detect common voltage in a DC state, while reporting a high frequency input which appears to be a common voltage as a safe state.

### BRIEF SUMMARY OF THE INVENTION

A low frequency detector determines whether the frequencies of first and second differential input signals are below a predetermined frequency threshold. An offset comparator circuit receives the differential input signal and generates a reference threshold voltage and respective first and second output signals, wherein the output signals are less than the reference threshold voltage if the differential input is within a predetermined offset range. First and second ECL-to-CMOS comparators generate status signals, where the first ECL-to-CMOS comparator has inputs coupled to the first output signal and the reference threshold voltage signal from the offset comparator circuit and the second ECL-to-CMOS comparator has inputs coupled to the second output signal and the reference threshold voltage signal from the offset comparator circuit. First and second timer circuits coupled to the first and second ECL-to-CMOS comparators generate a fault signal responsive to the status signals from the first and second comparators.

### BRIEF DESCRIPTION OF THE SEVERAL VIEWS OF THE DRAWINGS

For a more complete understanding of the present invention, and the advantages thereof, reference is now made to the following descriptions taken in conjunction with the accompanying drawings, in which:

FIG. 1 illustrates a block diagram of a conventional low frequency detector circuit;

FIG. 2 illustrates a block diagram of an improved low frequency detector circuit;

FIG. 3 illustrates a schematic representation of an offset comparator circuit;

FIG. 4 illustrates the operation of the offset comparator circuit of FIG. 3 for DC operation, or for sufficiently slow transitions;

FIG. 5 illustrates the operation of the offset comparator stage when INX-INY<offset for DC operation with a sufficiently slow transition;

FIG. 6 illustrates the operation of the offset comparator stage for sufficiently fast transitions of the differential input at which the E2C cannot function;

FIG. 7 illustrates the operation of the offset comparator circuit when the differential input condition exceeds offset of the comparator, but the frequencies of COMPX and COMPY, with continuous toggling of the differential input, are so high that the E2C does not function;

FIG. 8 illustrates the operation of the offset comparator circuit for the case where the differential input does not exceed the offset and thus COMPX and COMPY do not exceed the threshold (Vcomp) and where COMPX and COMPY toggle at a frequency that is beyond the capability of the E2C comparators;

FIG. 9 illustrates operation of the offset comparator circuit when the differential input exceeds the offset of the comparator, but a di-pulse width is too short for the E2C comparators to function;

FIG. 10 illustrates operation of the offset comparator circuit when the differential input condition does not exceed the offset of the comparator and the pulse width is short.

### DETAILED DESCRIPTION OF THE INVENTION

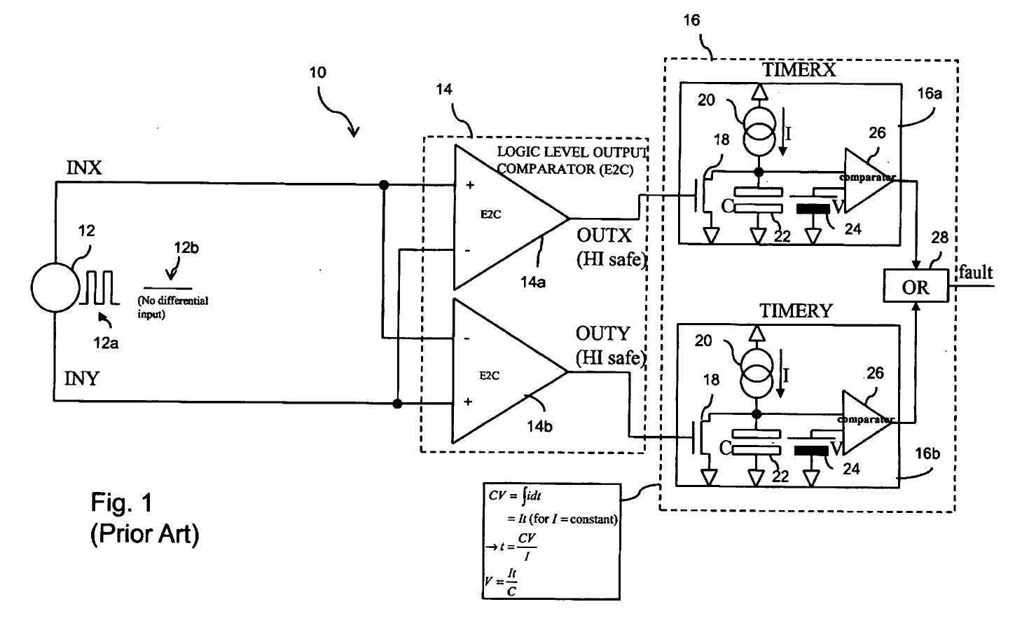

The present invention is best understood in relation to FIGS. 1-10 of the drawings, like numerals being used for like elements of the various drawings.

FIG. 1 illustrates a conventional detection circuit 10 that has the differential input 12 directly connected to the E2C circuit 14. The outputs of the E2C stage 14 are connected to a timer stage 16. The timer stage 16 outputs a fault signal if the frequency of the differential input becomes too low.

The differential input 12 is defined as the signal between INX and INY. During normal operation, this signal oscillates as shown at 12a, but under some conditions it may be at a DC level as shown at 12b. INX is coupled to a first input of E2C comparator 14a and a first input of E2C comparator 14b. INY is coupled to a second input of E2C comparator 14a and a second input of E2C comparator 14b. The output of E2C comparator 14a (OUTX) is coupled to the input of a first timing circuit (TIMERX) 16a. The output of E2C comparator 14b (OUTY) is coupled to the input of a second timing circuit 16b (TIMERY). The outputs of the timer circuits are coupled to a logical OR circuit 28. The output of the logical OR circuit 28 is the fault signal.

The timer circuits 16a and 16b are of conventional design. The gate of an NMOS transistor 18 is coupled to the OUT signal from the respective E2C comparator circuit 16a or 16b. A first source/drain of the NMOS transistor is coupled current source 20 supplying current I. A capacitor 22 (of capacitance C) is coupled between the first source/drain and ground. The second source/drain of NMOS transistor 18 is coupled to ground. A comparator 26 has a first input coupled to the node coupling the transistor 18, current source 20 and capacitor 22. The second input of comparator 26 is coupled to a reference voltage source 24 at voltage V.

In operation, the timers 16a and 16b work as follows (using timer 16a as an example). The current source 20 charges the capacitor 22 while the transistor 18 is turned off (i.e., OUTX is at a low logic level). Given sufficient time, the capacitor will charge sufficiently to drive the comparator 26 into a fault condition. However, if transistor 18 is turned on prior to this time, the capacitor is discharged (i.e., the timer is “reset”). During normal operation of the differential input having a sufficient frequency, the timer 16a is reset often enough that the capacitor 22 is always discharged prior to gaining sufficient voltage to drive comparator 26 to a fault condition.

However, when the frequency exceeds a certain threshold, the E2C stage 14 sees only the average of the differential signal 12. When this condition occurs, the outputs OUTX and OUTY are driven high—which prevents either timer 16a or 16b from indicating a fault. However, the E2C comparator cannot distinguish between a very high frequency differential signal and a differential signal that has a common voltage (i.e., the differential voltage is 0). In a situation where there is zero differential in the input signal, or a low differential, the E2C circuit will also drive OUTX and OUTY high to indicate a no-fault condition, even though the differential input signal is faulty.

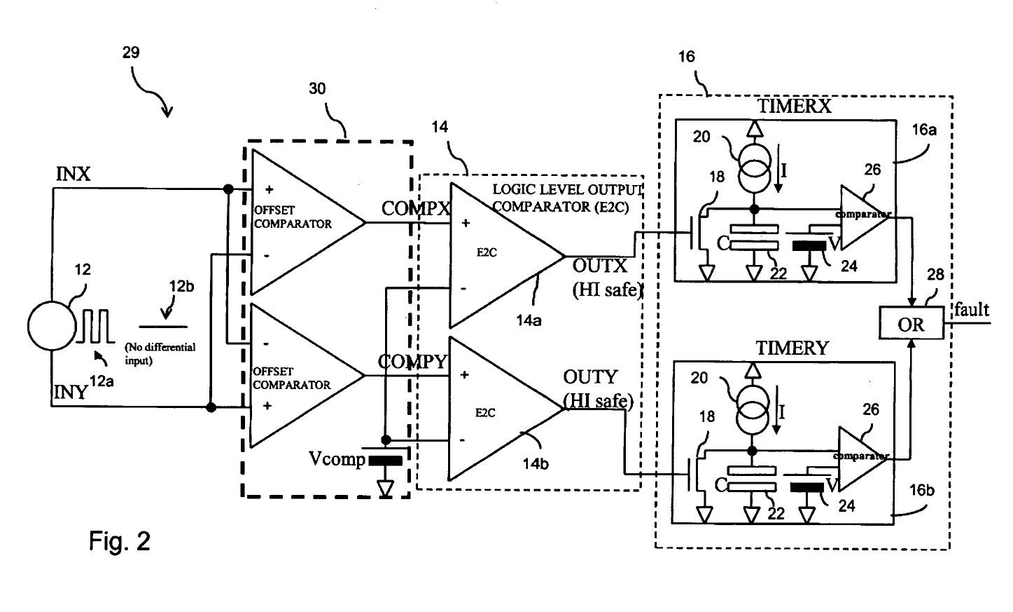

This circuit of FIG. 2 solves this problem by providing a low frequency detector circuit 29 that adds an offset comparator stage 30 between the differential input 12 and the E2C comparator stage 14. The offset comparator stage 30 generates three outputs: COMPX, COMPY and Vcomp. COMPX and Vcomp are coupled to the inputs of E2C comparator 14a and COMPY and Vcomp are coupled to the inputs of E2C comparator 14b.

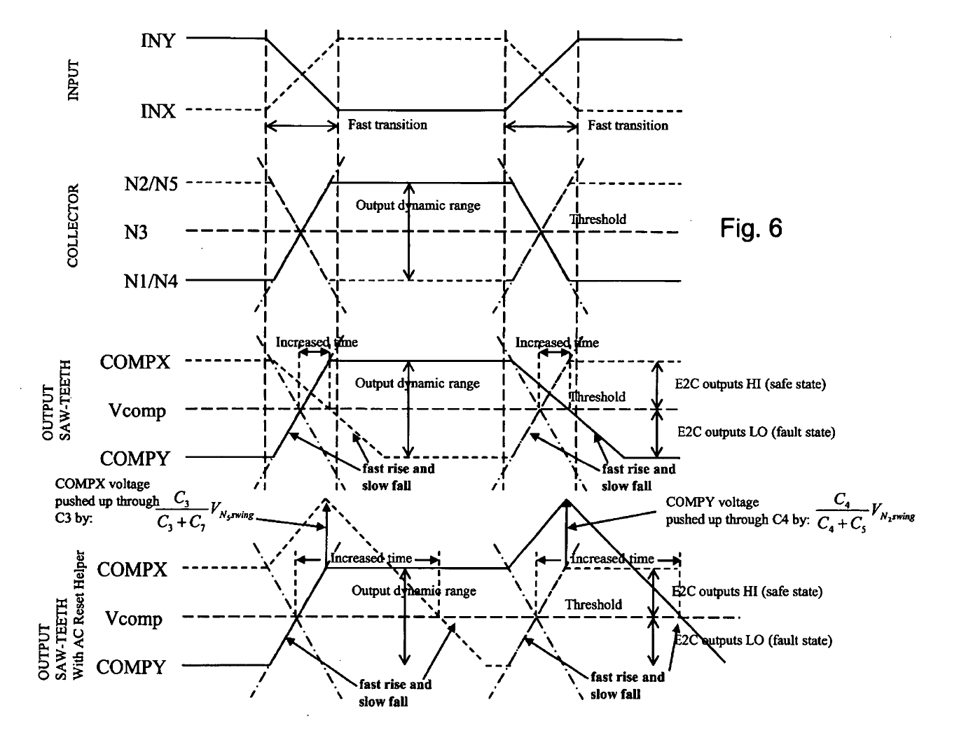

The offset comparator stage 30 performs a number of functions, described in greater detail below. First, any differential input less than a predetermined offset voltage is recognized as a fault, regardless of the frequency of the signal. When the differential input dips below the offset voltage, the COMPX and COMPY signals will fall below the Vcomp threshold limit to the E2C comparators. Second, the offset comparator stage 30 outputs a saw-tooth waveform at which has the effect of “slowing down” the input frequency as shown in connection with FIG. 6. An AC reset helper, described below, pushes the COMPX and COMPY voltages higher at the falling edge of the transitions to effectively slow down the datarate to the E2C comparator stage 14 at high frequencies. The circuit continues to function as required in the high frequency range to force a safe output to the timer section 18.

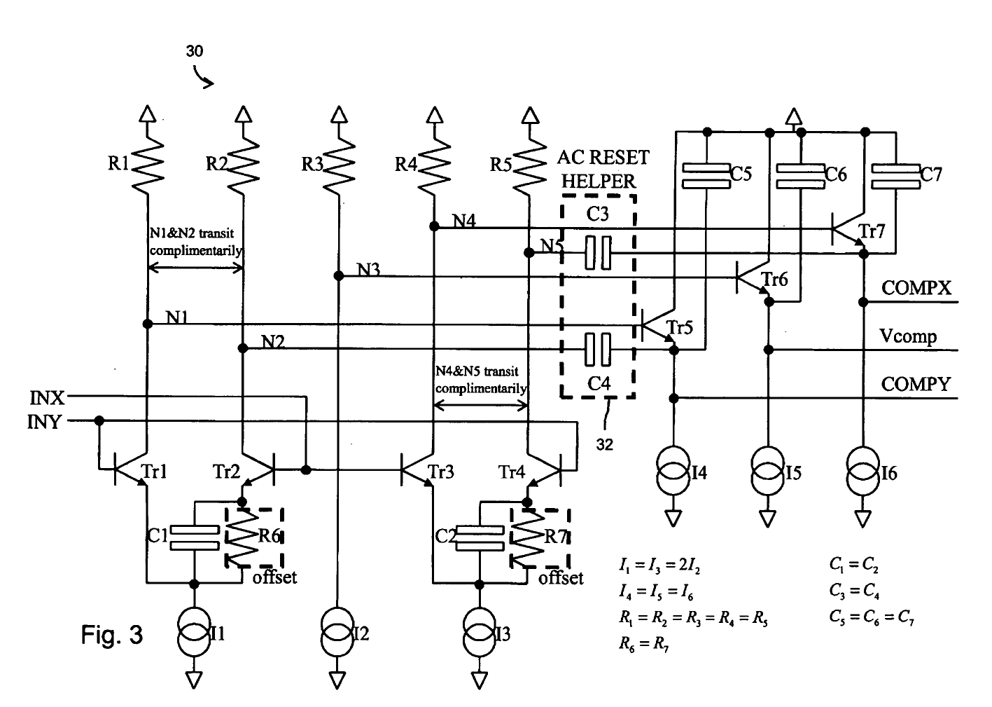

FIG. 3 illustrates an implementation of the offset comparator stage 30. Resistors R1, R2, R4 and R5 are coupled between a supplied voltage and the collectors of respective transistors Tr1, Tr2, Tr3 and Tr4. INX is coupled to the bases of Tr2 and Tr3 and INY is coupled to the bases of Tr1 and Tr4. The emitter of Tr1 is coupled to current source I1. The emitter of Tr2 is coupled to I1 through capacitor C1 and resistor R6 in parallel. The emitter of Tr3 is coupled to current source I3. The emitter of Tr4 is coupled to I3 through capacitor C2 and resistor R7 in parallel. Resistor R3 is coupled to current source I2. Node N1 lies between R1 and Tr1, node N2 lies between R2 and Tr2, node N3 lies between R3 and I2, node N4 lies between R4 and Tr3 and node N5 lies between R5 and Tr4. N1 is coupled to the base of transistor Tr5, N2 is coupled to the emitter of Tr5 through capacitor C4. N3 is coupled to the base of transistor Tr6. N4 is coupled to the base of transistor Tr7. N5 is coupled to the emitter of Tr7 through capacitor C3. Capacitors C3 and C4 are referred to herein as the AC reset helper 32. The collectors of Tr5, Tr6 and Tr7 are coupled to the supplied voltage. Capacitor C5 is coupled between the supplied voltage and the emitter of Tr5, capacitor C6 is coupled between the supplied voltage and the emitter of Tr6, and capacitor C7 is coupled between the supplied voltage and the emitter of Tr7. Current source I4 is coupled between the emitter of Tr5 and ground, current source I5 is coupled between the emitter of Tr6 and ground and current source I6 is coupled between Tr7 and ground. COMPX is the signal at the emitter of Tr7, COMPY is the signal at the emitter of Tr5 and Vcomp is the signal at the emitter of Tr6.

The values of the components listed herein will be described in connection with the name of the component. Thus, resistor R1 has a resistance value R1, capacitor C1 has a capacitance C1 and current source I1 provides a current flow I1. In the circuit of FIG. 3, I1=I3=2*I2; I4=I5=I6; R1=R2=R3=R4=R5; R6=R7; C1=C2; C3=C4; C5=C6=C7.

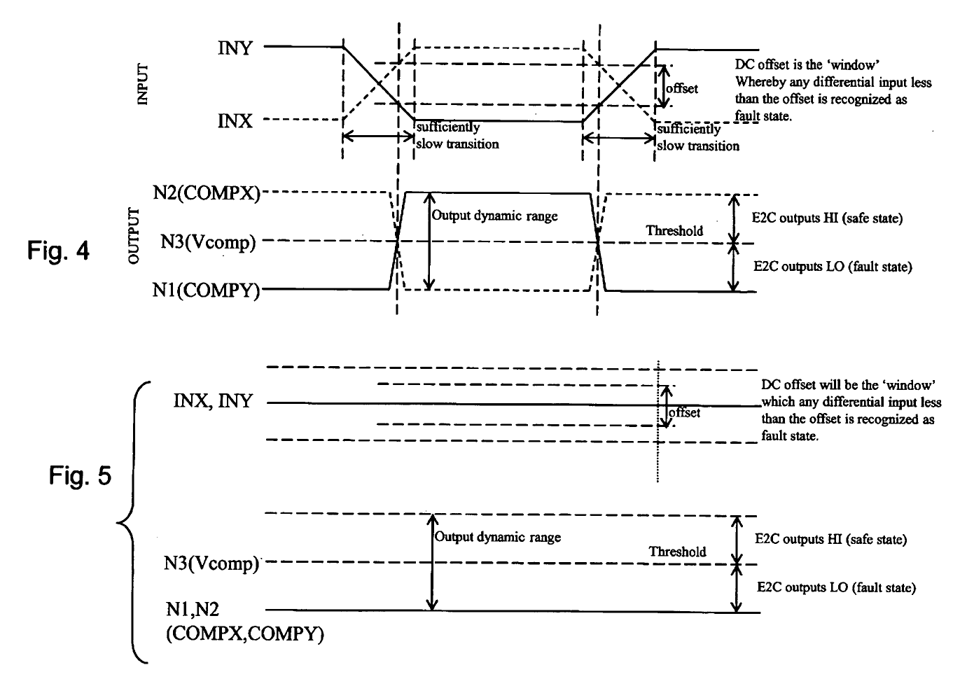

The operation of the offset comparator stage of FIG. 3 is illustrated in FIGS. 4-10. In FIG. 4, the operation is shown for DC operation, or for sufficiently slow transitions such that the capacitors do not affect the operation of the circuit. In the case of DC operation or sufficiently slow transitions, the effect of the capacitors in the circuit can be ignored.

An offset voltage range is defined as the range which determines whether the differential input is in a fault state. A differential input within the offset range is recognized as a fault state. The value of the DC offset voltage range is set by current sources I1 and I3 and respective resistors R6 and R7. The offset can be determined by the equation offset=I1*R6/2=I3*R7/2.

The output dynamic range of the offset comparator stage, i.e., the maximum difference between COMPX and COMPY is set by the maximum voltage swing at nodes N1, N2, N4 and N5 and can be determined by the equation output_dynamic_range=I1*R1=I1*R2. The threshold voltage (Vcomp) used for the comparators in the E2C comparator stage 14 can be determined by the equation threshold=I2*R3=output_dynamic_range/2 Vcomp is related to the offset—if INX or INY are within the offset range, then the respective output signal COMPX or COMPY will be less than Vcomp.

If COMPX and COMPY are greater than Vcomp, then the respective E2C comparator will generate a high (safe state) logic signal. Otherwise, if COMPX or COMPY is less than Vcomp, the respective E2C comparator 16a or 16b will generate a low (fault state signal). Thus, as shown in FIG. 4, when INX or INY are beyond the DC offset, the corresponding signal (COMPX and COMPY) from the offset comparator stage 30 will rise above Vcomp and a safe signal is generated by the corresponding E2C comparator.

FIG. 5 illustrates the operation of the offset comparator stage 30 when INX and INY are within the offset range for DC operation and sufficiently slow transition. Again, all capacitors in the offset comparator circuit can be ignored. In this case, however, N1, N2, COMPX and COMPY will be less than the N3 or Vcomp threshold. Thus, the E2C comparators will see COMPX and COMPY signals that are less than Vcomp and generate low (fault state) logic signals.

FIG. 6 illustrates an important aspect of the invention for sufficiently fast transitions of the differential input, where the E2C cannot function. At sufficiently fast transitions, the rise times COMPX and COMPY are given by the emitter follower charge and the fall times are given from the discharge of capacitors C4 and C5, or C3 and C7, by the current sources I4 and I6. The fast rise of the COMPX and COMPY signals and slow fall increases the time between the COMPX or COMPY rising above Vcomp and subsequently falling below Vcomp, thereby effectively decreasing the frequency to the E2C comparators. Thus, the E2C comparators effectively operate at higher datarates. The frequency is effectively decreased further by the AC reset helper 32, described in greater detail below.

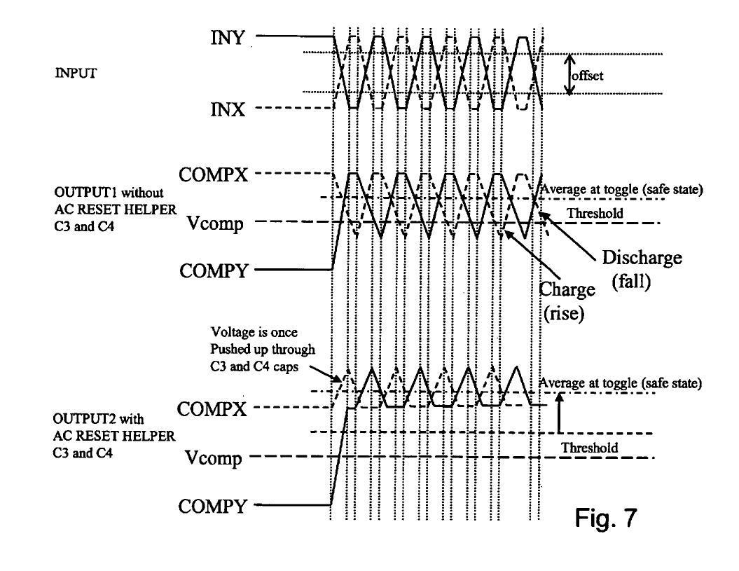

FIG. 7 illustrates the operation of the offset comparator circuit 30 when the differential input condition exceeds offset of the comparator, but the frequencies of COMPX and COMPY, with continuous toggling of the differential input, are so high that the E2C does not function, but instead sees the average voltage of the inputs COMPX and COMPY. In the illustrated case, the average voltages of COMPX and COMPY exceed the threshold (Vcomp) of E2C due to the difference between rise time and fall time, and the E2C circuits output a high (safe state) logic level.

Without the AC reset helper 32 of C3 and C4, the E2C comparator stage 14 would only see the average voltage on COMPX and COMPY—which would be recognized as safe. The COMPX and COMPY nodes would be charged by emitter followers at Tr5 and Tr7, and discharged by the current sources I4 and I6 by the formula V=It/C, where I is the current of source I4 or I6 and C is the capacitance of C5 or C7.

With the AC reset helper 32, however, the average voltages at COMPX and COMPY are automatically pushed up by N5 and N2, respectively. The increase of COMPX and COMPY places the inputs to the E2C comparator stage 14 in a safer state, which is well above Vcomp at all times. The amount of additional voltage provided by N2 and N5 is given by the formula

$$\frac{{C}_{4}}{{C}_{4} + {C}_{5}} {V}_{{N}_{2} swing} = \frac{{C}_{3}}{{C}_{3} + {C}_{7}} {V}_{{N}_{5} swing} .$$

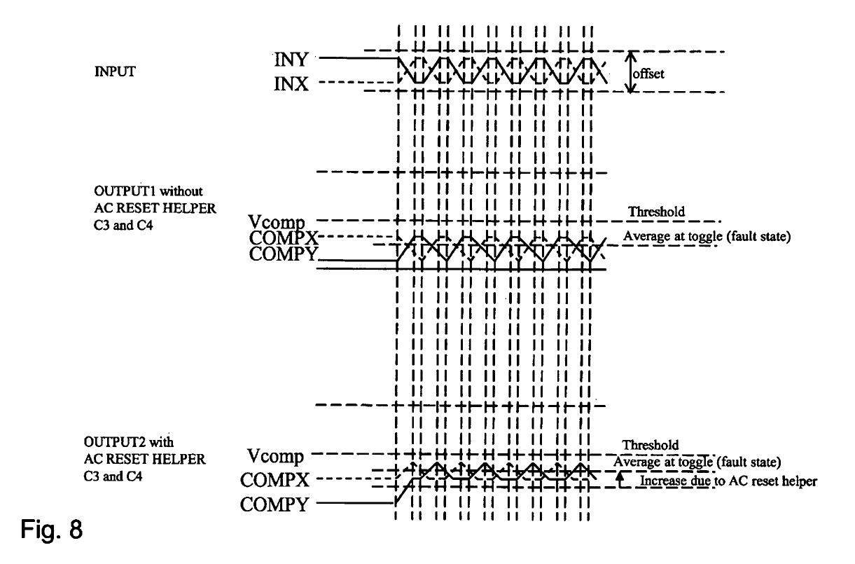

FIG. 8 illustrates the operation of the offset comparator circuit for the case where the differential input does not exceed the offset and thus COMPX and COMPY do not exceed the threshold (Vcomp) and where COMPX and COMPY toggle at a frequency that is beyond the capability of the E2C comparators.

Without the AC reset helper 32, COMPX and COMPY will be below Vcomp, and the E2C comparators will output a low (fault state) logic signal to the timer stage 16, which is the correct state.

With the AC rest helper 32, COMPX and COMPY will also be below Vcomp, and the E2C comparators will output a low (fault state) logic level signal to the timer stage 16, which is correct. The average voltages of COMPX

$$\frac{{C}_{4}}{{C}_{4} + {C}_{5}} {V}_{{N}_{2} swing} = \frac{{C}_{3}}{{C}_{3} + {C}_{7}} {V}_{{N}_{5} swing} ,$$

and COMPY will be pushed by C3 and C4 by but because the voltage swings of N2 and N5 (V_{N}_{₂}_{swing},V_{N}_{₅}_{swing}) will be small due to the small differential voltage, COMPX and COMPY will be pushed up only slightly.

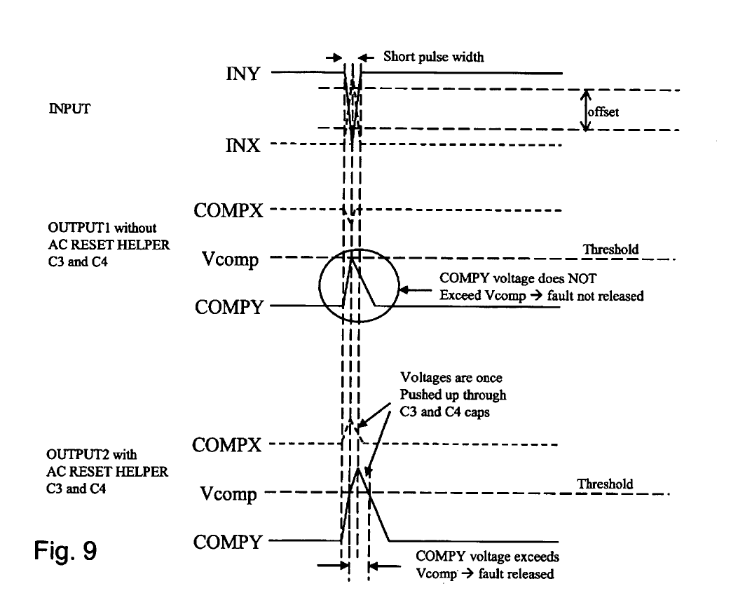

FIG. 9 illustrates operation of the offset comparator circuit 30 when the differential input exceeds the offset of the comparator, but a di-pulse width is too short for the E2C comparators to function. When the differential signal width is at its minimum (i.e., a di-pulse) at the highest datarate, it presents the most difficult situation for the E2C comparators to reset, since the resetting side of the E2C input (COMPX or COMPY) starts from the lowest voltage to rise and start falling on the next transition. In this case, the AC reset helping capacitors 32 boosting the COMPX and COMPY voltages to exceed Vcomp, or to exceed Vcomp for a longer period of time, so that the E2C comparators can reset the timer stage 16.

As shown in FIG. 9, without the AC reset helper 32, if the di-pulse is too short, one of the COMP signals may not exceed Vcomp, or may not exceed Vcomp for a sufficient time, to release the fault condition. With the AC reset helper 32, COMPX and COMPY voltages are pushed up and exceed Vcomp for a longer time, allowing the E2C comparators enough time to reset the timer stage 14.

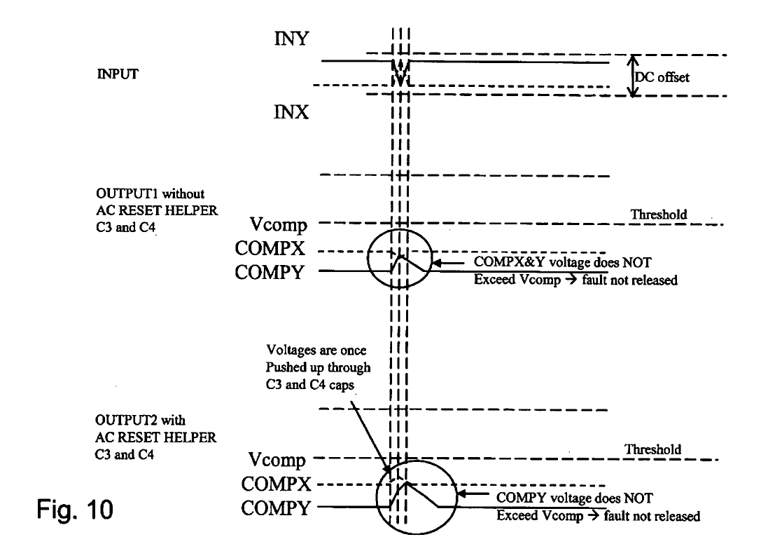

FIG. 10 illustrates operation of the offset comparator circuit 30 when the differential input condition does not exceed the offset of the comparator and the pulse width is short. In this instance, the circuit should not drive COMPX or COMPY high. Without the reset helper, when the input di-pulse is too short and the differential input does not exceed the offset, COMPX and COMPY remain below Vcomp, and the fault is not released. This is the correct function. With the AC reset helper, COMPX and COMPY will still not exceed Vcomp, because the voltage swing at N2 and N5 is so small that the C3 and C4 capacitors only slightly increase the voltage of the signals according to the formula

$$\frac{{C}_{3}}{{C}_{3} + {C}_{7}} {V}_{{N}_{5} swing} ( or \frac{{C}_{4}}{{C}_{4} + {C}_{5}} {V}_{{N}_{2} swing} ) ,$$

as was the case in connection with FIG. 8.

The present invention provides significant advantages over the prior art. First, the addition of the offset comparator to a low frequency detector circuit enables the detector to detect both low frequency and common voltage errors. Second, the AC reset help capacitors 32 improves performance of the detector in the high frequency range—both in with a continuous input pattern and with di-pulses in random patterns.

Although the Detailed Description of the invention has been directed to certain exemplary embodiments, various modifications of these embodiments, as well as alternative embodiments, will be suggested to those skilled in the art. The invention encompasses any modifications or alternative embodiments that fall within the scope of the Claims.

1. A low frequency detector for determining whether the frequency of a differential input signal is below a predetermined frequency threshold, comprising:
an offset comparator circuit for receiving first and second complementary differential input signals and generating a reference threshold voltage and respective first and second output signals, wherein the output signals are less than the reference threshold voltage if the differential input is within a predetermined offset voltage range;
first and second ECL-to-CMOS comparators for generating status signals, the first ECL-to-CMOS comparator having inputs coupled to the first output signal and the reference threshold voltage signal from the offset comparator circuit and the second ECL-to-CMOS comparator having inputs coupled to the second output signal and the reference threshold voltage signal from the offset comparator circuit; and
first and second timer circuits coupled to the first and second ECL-to-CMOS comparators for generating a fault signal responsive to the status signals from the first and second comparators.

2. The low frequency detector circuit of claim 1 wherein the offset comparator circuit further comprises circuitry for increasing the voltage of the output signals within a range of frequencies such that the increase in voltage of an output signal is dependent upon a voltage swing of the respective differential input, such that an output signal corresponding to a differential input signal with a high voltage swing is increased more than an output signal corresponding to a differential input signal with a low voltage swing.

3. The low frequency detector of claim 2 wherein the circuitry for increasing the voltage comprises first and second capacitors coupled between respective first and second output nodes and internal nodes which swing in voltage responsive to the signal on the differential input signals.

4. The low frequency detector circuit of claim 1 wherein the offset comparator circuit provides output signals with a faster rise time than fall time.

5. The low frequency detector circuit of claim 4 wherein respective capacitors are coupled to first and second output nodes.

6. A low frequency detector circuit comprising:
circuitry for detecting whether a differential input signal, comprising first and second complementary signals, has a frequency below a predetermined threshold frequency; and
circuitry for detecting whether the differential input signal is within a predetermined voltage range.

7. The low frequency detector circuit of claim 6 wherein the circuitry for detecting whether a differential input signal has a frequency below a predetermined threshold frequency comprises ECL-to-CMOS comparators for comparing the relative voltage of two input signals.

8. The low frequency detector circuit of claim 7 wherein the ECL-to-CMOS comparators generate a predetermined signal once the frequency of the input signals to the comparators passes a known level at which the comparators see the average voltage of each input signal.

9. The low frequency detector circuit of claim 8 wherein the circuitry for detecting whether a differential input signal has a frequency below a predetermined threshold frequency further comprises circuitry for generating a threshold voltage signal and generating first and second output signals having a predetermined relationship to the threshold voltage signal responsive to whether the first and second complementary input signals are within a predetermined offset voltage range.

10. The low frequency detector of claim 9 wherein the circuitry for detecting whether a differential input signal has a frequency below a predetermined threshold frequency further comprises circuitry for increasing the voltage of the output signals responsive to voltage swings of the complementary input signals.

11. The low frequency detector of claim 10 and further comprising circuitry for generating output signals with faster rise times than fall times.

12. A method of detecting whether the frequency of a differential input signal is below a predetermined frequency threshold, comprising the steps of:
receiving the first and second complementary differential input signals;
generating a reference threshold voltage and respective first and second output signals, wherein the output signals are less than the reference threshold voltage if the differential input is within a predetermined offset range;
generating status signals with first and second ECL-to-CMOS comparators, the first ECL-to-CMOS comparator having inputs coupled to the first output signal and the reference threshold voltage signal from the offset comparator circuit and the second ECL-to-CMOS comparator having inputs coupled to the second output signal and the reference threshold voltage signal from the offset comparator circuit; and
generating fault signals responsive to the status signals.

13. The method of claim 12 wherein the step of generating a reference threshold voltage and respective first and second output signals comprises the step of increasing the voltage of the output signals within a range of frequencies such that the increase in voltage of an output signal is dependent upon a voltage swing of the respective differential input, such that an output signal corresponding to a differential input signal with a high voltage swing is increased more than an output signal corresponding to a differential input signal with a low voltage swing.

14. The low frequency detector circuit of claim 12 wherein the step of generating a reference threshold voltage and respective first and second output signals includes the step of generating output signals with a faster rise time than fall time.
